(19) United States
(12) Patent Application Publication
(10) Pub. No.: US 2026/0090462 A1
(43) Pub. Date: Mar. 26, 2026

(54) POWER SEMICONDUCTOR MODULE AND METHOD FOR MANUFACTURING THE SAME

(71) Applicant: Infineon Technologies AG, Neubiberg (DE)

(72) Inventor: Jens Figge, Diemelsee (DE)

(21) Appl. No.: 19/319,835

(22) Filed: Sep. 5, 2025

(30) Foreign Application Priority Data
Sep. 24, 2024 (DE) 102024209140.5

(51) Int. Cl. H01L 23/047; H01L 21/48; H01L 23/00; H01L 23/10; H01L 25/07; H01L 25/11; H10D 80/20

(52) U.S. Cl. CPC H10W 76/134; H10W 76/01; H10W 76/60; H10W 90/00; H10D 80/251; H10W 72/07554; H10W 72/547; H10W 76/10; H10W 90/755; H10W 90/794

(57) ABSTRACT

The present disclosure relates to a power semiconductor module including: a carrier; a plurality of semiconductor dies mounted onto the carrier; a housing including a frame enclosing the carrier circumferentially; a first external connection electrically connected to a first subset of the semiconductor dies, the first external connection protruding laterally from the housing at a first level; and an insert including an electrically isolating material and a second external connection mounted onto the electrically isolating material. The insert is at least partially mounted to the frame and at least partially covers the carrier and/or the first subset of the plurality of semiconductor dies. The second external connection is connected to a second subset of the plurality of semiconductor dies. The second external connection protrudes from the housing.

### TECHNICAL FIELD

The present disclosure relates to a power semiconductor module, in particular to the routing and wiring inside the power semiconductor module.

### BACKGROUND

Power semiconductor modules used in converter or inverter applications typically comprise a plurality of semiconductor dies, e.g. in a half-, or full-bridge configuration, in two-level or in a multi-level configuration. The semiconductor dies are usually mounted onto a substrate comprising a dielectric layer with a metal layer on top which provides routing structures for the desired configuration. The size of the power semiconductor module is thus not only dependent on the die content inside the power semiconductor module but also on the spacing required for the respective routing structures on the substrate, which include power but also signal routing inside the power semiconductor module. Especially electrically isolated substrates such as ceramics are rather expensive, and a different substrate layout may be required for different die contents/circuit configurations which may require different tooling based on different substrate sizes.

These and other limitations are addressed by the power semiconductor module and method for manufacturing thereof disclosed in this application.

### SUMMARY

A power semiconductor module comprises a carrier, a plurality of semiconductor dies mounted onto the carrier, a housing comprising a frame enclosing the carrier circumferentially, a first external connection electrically connected to a first subset of the plurality of semiconductor dies, the first external connection protruding laterally from the frame at a first level, an insert comprising an electrically isolating material and a second external connection mounted onto the electrically isolating material, wherein the insert is at least partially mounted to the frame and at least partially covers the carrier and/or the first subset of the plurality of semiconductor dies, and wherein the second extern al connection is connected to a second subset of the plurality of semiconductor dies, the second external connection protruding from the housing.

A method for manufacturing a power semiconductor module comprises providing a carrier, mounting a plurality of semiconductor dies onto the carrier, enclosing the carrier circumferentially by a housing comprising a frame, providing a first external connection electrically connected to a first subset of the plurality of semiconductor dies, the first external connection protruding laterally from the frame at a first level, mounting an electrically isolating insert having a first and an opposing second side to at least parts of the frame and at least partially covering the carrier and/or the first subset of the plurality of semiconductor dies by the electrically isolating insert and mounting a second external connection electrically connected to a second subset of the plurality of semiconductor dies onto the electrically isolating insert and, the second external connection protruding from the housing.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a top view onto a carrier portion of a framed power semiconductor module according to a first example.

FIG. 2 shows an insert mountable to the carrier portion of the framed power semiconductor module according to FIG. 1.

FIG. 3 illustrates the power semiconductor module shown in FIG. 1 including the insert shown in FIG. 2.

FIG. 4 shows an exemplary side view of a module shown in FIG. 3 wherein the frame along the longitudinal side has been omitted.

FIG. 5 shows a further exemplary side view of a module in FIG. 3 wherein the frame along the longitudinal side has been omitted.

FIG. 6 shows a further exemplary insert with additional routing structures compared to FIG. 2.

FIG. 7 illustrates a power semiconductor module with the insert shown in FIG. 6.

FIG. 8 shows an exemplary side view of a module shown in FIG. 7 wherein the frame along the longitudinal side has been omitted.

### DETAILED DESCRIPTION

The examples described herein provide a power semiconductor module in which a further routing level is introduced allowing a more flexible design of the routing path as well as more efficient use of the basic routing level onto which the semiconductor dies are mounted.

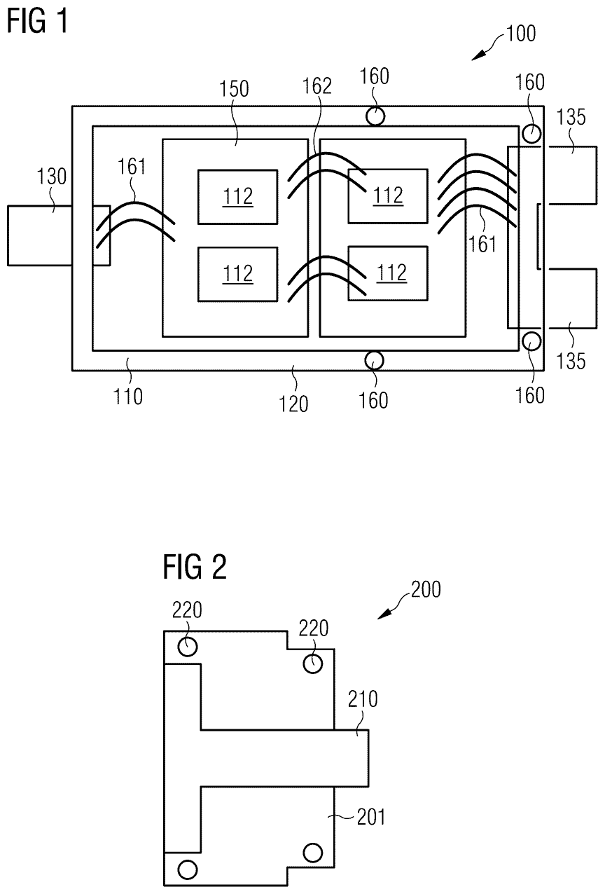

FIG. 1 shows a carrier 110 of a power semiconductor module 100. A plurality of semiconductor dies 112 may be mounted onto the carrier 110. The carrier 110 may comprise one or more substrates 150. The substrates 150 may be formed of an electrically isolating layer, such as but not limited to a ceramic layer, sandwiched in metallic layers such as Cu or Al. Each of the substrates may be of the type direct copper bonded (DCB) substrates, active metal brazed (AMB) substrates or insulated metal substrate (IMS), direct aluminum bonded (DAB) substrate etc. The metallic layers may be structured (not shown) to provide a required routing along and between the plurality of dies 112 mounted onto the carrier 110. The carrier may comprise a baseplate wherein the one or more substrates 150 are mounted onto the baseplate. Alternatively, the one or more substrates 150 may also be inserted into the baseplate. Nevertheless, a baseplate is not necessarily required, the housing can also be placed on the one or more substrates 150.

The type and number of semiconductor dies 112 may depend on the application for which the power semiconductor module is designed. The semiconductor dies may be connected in a half-bridge configuration as exemplary indicated in FIG. 1, but may also be provided in any other configuration such as a full bridge, multi-level, etc. For example, the semiconductor dies 112 may be power MOSFET (metal-oxide-semiconductor field-effect transistor) die, HEMT (high-electron mobility transistor) dies, IGBT (insulated gate bipolar transistor) dies, power diode dies, sensors etc.

A housing comprising a frame 120 encloses the carrier 110 circumferentially. The frame comprises an electrically insulative material such as but not limited to a plastic. A first external connection 135 electrically connected to a first subset of the plurality of semiconductor dies 112 protrudes laterally from the frame 120. The first external connection 135 may be a first power terminal providing a voltage supply, e.g. DC+ or DC−, to the corresponding first subset of semiconductor dies 112. Ground reference point may be provided by the carrier to which the frame 120 may be attached. The carrier 110 may be attached to a cooler (not shown) also on ground. A further external connection 130 may protrude from the frame. In the example shown in FIG. 1 the further external connection 130 protrudes from the frame at an opposing side of the first external connection 135. In an AC/DC converter structure the further external connection 130 may be the AC power terminal.

The internal connection 161 between the external connections and the plurality of semiconductor dies 112 may be provided by wires, ribbons or clips as well as the routing structures of the one or more substrates 150. The internal connection 161 may be soldered, sintered or welded to the first external connection 135 and or to the substrate 150.

A fixing structure 160, such as but not limited to heat stake domes, screws, clamping pieces etc., is provided on the carrier 110. A heat stake dome consists of a plastic or metal dome-shaped component with a protruding pin or stud in the center. The pin is designed to be inserted into a hole on the PCB, and the dome is then melted or deformed using heat and pressure to create a strong mechanical bond between the pin and the surrounding material. This process is often referred to as “heat staking” or “thermal staking.”

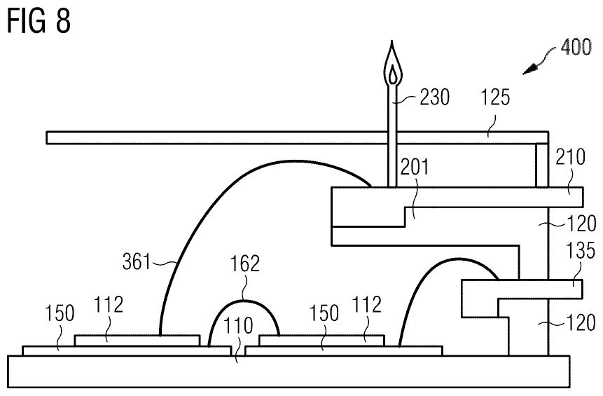

The fixing structure 160 may inter alia be used to receive and fix a lid (shown in FIG. 8) to cover the power semiconductor module and protect its content. The fixing structures 160 may also receive an insert 200 as shown in FIG. 2.

The insert 200 comprises an electrically isolating material 201 and a second external connection 210 mounted onto the electrically isolating material 201, wherein the second external connection 210 may at least partially be inserted, e.g. (over-)molded, in the electrically isolating material 201. Holes 220 in the insert may be used to align the insert 200 with and fix the insert 200 to the frame 120 of the power semiconductor module 100. The fixing structures 160 may be inserted into the holes 220. In case heat stake domes are used, the top of one or more of the domes may be melted after being pushed through the holes 220. The top deforms such that it cannot retract through the hole 220 and thus fixes the insert 200 in position. The fixation does not have to happen immediately after the dome has been pushed through the hole 220 of the insert 200. Further components may be placed on top, for instance a lid 125 to cover the entire power semiconductor module 100 from the top. Lid 125 and insert 200 may be mounted using the same or different fixing structures 160. The lid 125 may also be fixed using additional fixing structures of the same type or of a different type then fixing structures 160.

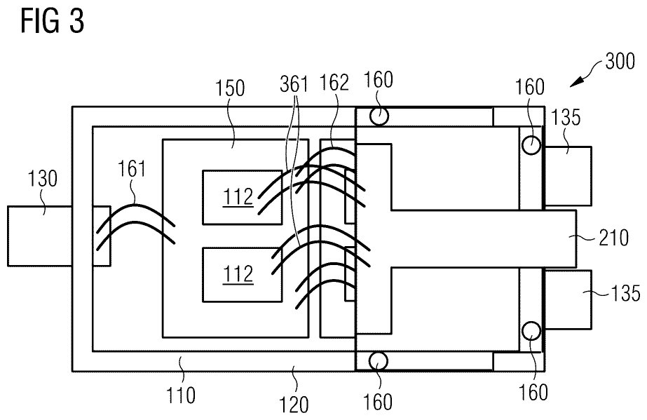

FIG. 3 shows the insert 200 partially mounted to the frame 120, e.g. three sides are mounted to the top of the frame. The insert 200 at least partially covers the carrier 110 and/or the first subset of the plurality of semiconductor dies 112.

The second external connection 210 is electrically connected to a second subset of the plurality of semiconductor dies 112 via electrical connections 361. The connection may be direct or indirectly via the substrate, e.g. via ribbons, wires or clips. In the example shown in FIG. 3 the second external connection 210 protrudes laterally from the housing. The second external connection 210 may be a second power terminal providing a voltage supply, e.g. DC− or DC+ to the corresponding second subset of semiconductor dies 112. In an example the first external connection 135 may sandwich the second external connection 210 as shown in FIG. 3, e.g. DC+|DC−|DC+ or DC−|DC+|DC−. Alternatively, the second external connection may also be the AC terminal, sandwiched by two DC terminals, e.g. DC+ and DC− separated from one another.

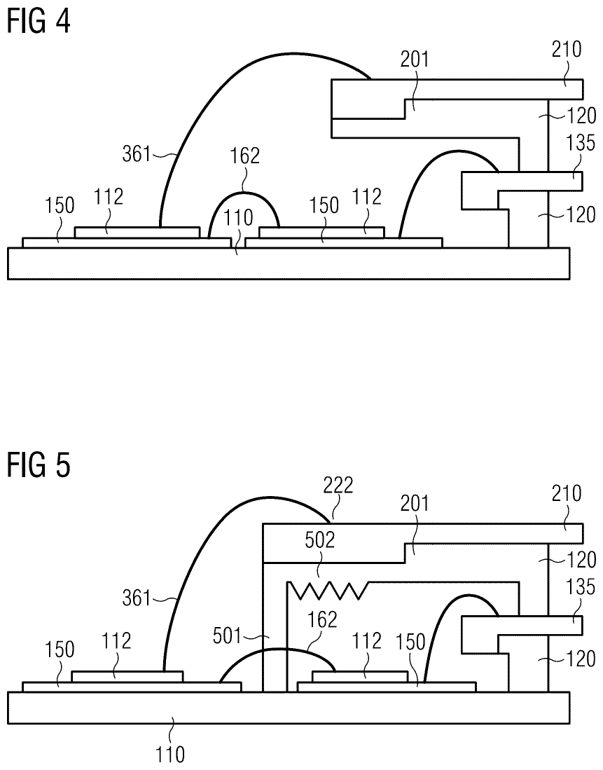

FIG. 4 schematically shows a sideview of the module illustrated in FIG. 3, wherein the lateral frame wall has been omitted for illustrative purposes. The first external connection 135 protrudes from the housing at a first level, while the second external connection 210 protrudes from the housing at a second level, wherein the second level is different from the first level, e.g. a higher level compared to the carrier 110. The insert 200 provides a second level for signal and power routing that may go in parallel with the routing on the first level and may thus not only save space at the carrier level but may also enhance the module performance in view of stray inductances. In FIGS. 1 and 4 the fixing structures 160 are shown as separate structures inside the module. Preferably, the fixing structures 160 are however part of the frame 120 wherein they may even be monolithically formed with the frame 120.

In the example illustrated in FIG. 5, the insert further comprises a support structure on the lower side of the insert facing the substrate. The support structure may be positioned below an internal connection region 222 of the insert, e.g. the region where the wires, ribbons, clips or other electrical connections 361 are attached at the insert, e.g. bonded, welded etc., to provide the signal or power routing from the substrate level. The support structure 501 may be in contact with the carrier 110. In an example, the insert may have support columns or walls integrally formed from the electrically isolating material 201. The support structure 501 could be placed above the carrier 110 or even above the substrate 150 since it is electrically isolating.

Alternatively or in addition, a brace or serrated profile 502 that is not in contact with the carrier 110 may be formed on the lower side of the insert facing the substrate, in particular below the internal connection region.

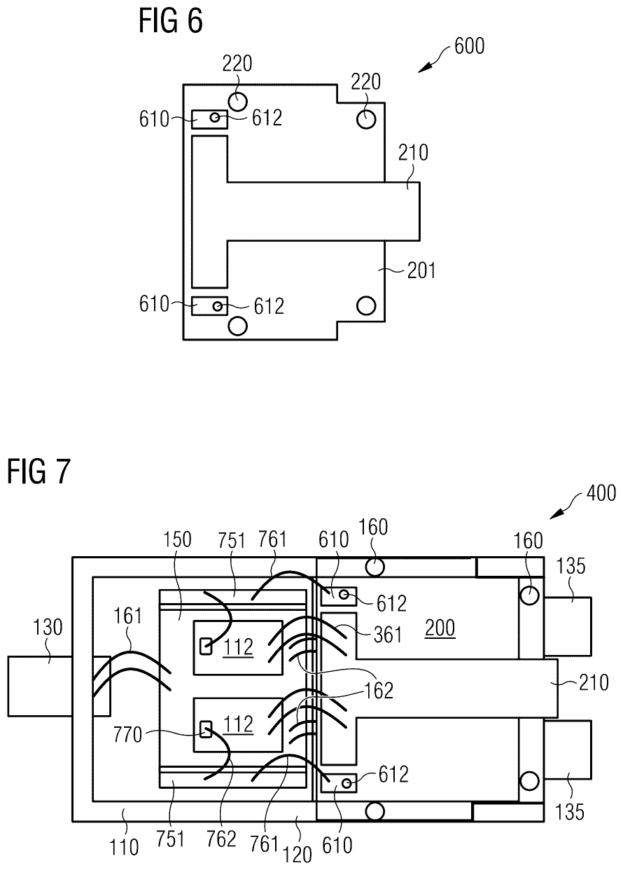

FIG. 6 shows a further variant of the insert 600 with a further routing structure 610 additional and separate from the routing structure belonging to the second external connection 210. A pin 612, such as but not limited to a press-fit pin, may be connected to the further routing structure 610. The pin may protrude from the housing in a lateral or vertical direction. In an example, the further routing structure 610 and the pin 612 may be used for signal routing and the pin protrudes from the housing orthogonal to the carrier, e.g. from the lid 125 of the module if it has one. The pin may then be connected to a driver board mounted on top of the power semiconductor module.

FIG. 7 illustrates a power semiconductor module comprising the insert of FIG. 6. The further routing structure 610 is connected to a separate island 751 on the substrate 150 via a bond wire or ribbon or alternatively a clip. A control pad 770 of the semiconductor dies 112 may then be connected to the island 751. Alternatively, the control pad 770 e.g. gate or sensor contact may also be directly connected to the further routing structure 610 via an electrical connection such as, a wire, a ribbon or a clip.

The insert 200 may provide further routing structures or a rerouting from signal or power paths received from the substrate level. Furthermore, the insert 200 may provide space for sensors or other circuitry. As an example, a current sensor (not shown) may be provided on the top or bottom side of the insert 200 to measure a current running through one of the external power connections, e.g. 210 and/or 135. Accordingly, the second level provides further flexibility with regard to routing and the design/arrangement of components within the module. Furthermore, the second level routing layer would also provide space for further semiconductor chips, such as but not limited to a driver chip.

FIG. 8 schematically illustrates the arrangement of FIG. 7 as seen from the side wherein the longitudinal frame wall has been omitted for illustrative purposes. The figure will only be described for the differences between FIG. 8 and previous FIG. 4. In FIG. 8 the additional vertical press fit pin 230 is illustrated. It protrudes through the lid 125 and can be pressed into a driver board or any other external circuitry. In FIG. 8 the vertical press fit pin is shown as an additional external contact routed onto the insert. However, the second external power connection may be constructed from one or more vertical press fit pins and thus protrude from the lid instead of laterally from the frame.

To protect the inner components from environmental factors, such as moisture, dust, and mechanical stress and to electrically isolate them each of the power modules shown above may be filled with a potting material, such as but not limited to a type of epoxy resin or silicone-based compound.
1. Example: A power semiconductor module comprising a carrier, a plurality of semiconductor dies mounted onto the carrier, a housing comprising a frame enclosing the carrier circumferentially, a first external connection electrically connected to a first subset of the plurality of semiconductor dies, the first external connection protruding laterally from the housing at a first level, an insert comprising an electrically isolating material and a second external mounted onto the electrically isolating material, wherein the insert is at least partially mounted to the frame and at least partially covers the carrier and/or the first subset of the plurality of semiconductor dies; and wherein the second external connection is connected to a second subset of the plurality of semiconductor dies, the second external connection protruding from the housing.
2. Example: The power semiconductor module of example 1 wherein the second external connection protrudes laterally from the housing at a second level different from the first level.
3. Example: The power semiconductor module of any of the preceding examples, wherein the first external connection and the second external connection protrude from a same side of the frame.
4. Example: The power semiconductor module of example 3, wherein the first and second external connection are at least partially stacked over one another outside the frame, separated by the electrically isolating material of the insert.
5. Example: The power semiconductor module of example 3, wherein the first external connection protrudes from the frame laterally spaced apart from the second external connection.
6. Example: The power semiconductor module of example 1 wherein the housing further comprises a lid mounted onto the frame and the second external connection protrudes from the lid.
7. Example: The power semiconductor module of any of the preceding examples, wherein the insert is mounted to the frame via heat stake domes.
8. Example: The power semiconductor module of any of the preceding examples, wherein the second external connection comprises a bonding region and the insert comprises a support structure below the bonding region.
9. Example: The power semiconductor module of example 8, wherein the support structure is in contact with the carrier.
10. Example: The power semiconductor module of example 8 wherein the support structure is formed as a brace or serrated profile that is not in contact with the carrier.
11. Example: The power semiconductor module of any of the preceding examples, wherein the carrier comprises a common dielectric layer and a structured metal layer, wherein the first subset of the plurality of semiconductor dies is mounted to a first island of the structured metal layer and the second subset of the plurality of semiconductor dies is mounted to a second island of the structured metal layer, the second island being disjunct from the first island.
12. Example: The power semiconductor module of any of examples 1 to 10, wherein the carrier comprises two or more dielectric substrates disjunct from one another and with a respective metal layer on top, wherein the first subset of the plurality of semiconductor dies is mounted to a first one of the dielectric substrates and the second subset of the plurality of semiconductor dies is mounted to a second one of the dielectric substrates.
13. Example: A method for manufacturing a power semiconductor module comprising: providing a carrier, mounting a plurality of semiconductor dies onto the carrier, enclosing the carrier circumferentially by a housing comprising a frame, providing a first external connection electrically connected to a first subset of the plurality of semiconductor dies, the first external connection protruding laterally from the frame at a first level, mounting an insert onto the frame, the insert comprising an electrically isolating material and a second external connection mounted onto or overmolded to the electrically isolating material, wherein the insert at least partially covers the carrier and/or the first subset of the plurality of semiconductor dies; and wherein the second external connection is connected to a second subset of the plurality of semiconductor dies, the second external connection protruding from the housing.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power semiconductor module, comprising:
a carrier;
a plurality of semiconductor dies mounted onto the carrier;
a housing comprising a frame enclosing the carrier circumferentially;
a first external connection electrically connected to a first subset of the plurality of semiconductor dies, the first external connection protruding laterally from the housing at a first level;
an insert comprising an electrically isolating material and a second external connection mounted onto the electrically isolating material,
wherein the insert is at least partially mounted to the frame and at least partially covers the carrier and/or the first subset of the plurality of semiconductor dies, and
wherein the second external connection is connected to a second subset of the plurality of semiconductor dies, the second external connection protruding from the housing.

2. The power semiconductor module of claim 1, wherein the second external connection protrudes laterally from the housing at a second level different from the first level.

3. The power semiconductor module of claim 1, wherein the first external connection and the second external connection protrude from a same side of the frame.

4. The power semiconductor module of claim 3, wherein the first external connection and the second external connection are at least partially stacked over one another outside the frame, and separated by the electrically isolating material of the insert.

5. The power semiconductor module of claim 3, wherein the first external connection protrudes from the frame laterally spaced apart from the second external connection.

6. The power semiconductor module of claim 1, wherein the housing further comprises a lid mounted onto the frame, and wherein the second external connection protrudes from the lid.

7. The power semiconductor module of claim 1, wherein the insert is mounted to the frame via a plurality of heat stake domes.

8. The power semiconductor module of claim 1, wherein the second external connection comprises an internal connection region, and wherein the insert comprises a support structure below the internal connection region.

9. The power semiconductor module of claim 8, wherein the support structure is in contact with the carrier.

10. The power semiconductor module of claim 8, wherein the support structure is formed as a brace or serrated profile that is not in contact with the carrier.

11. A method for manufacturing a power semiconductor module, the method comprising:
mounting a plurality of semiconductor dies onto a carrier;
enclosing the carrier circumferentially by a housing comprising a frame;
providing a first external connection electrically connected to a first subset of the plurality of semiconductor dies, the first external connection protruding laterally from the frame at a first level;
mounting an insert onto the frame, the insert comprising an electrically isolating material and a second external connection mounted onto the electrically isolating material,
wherein the insert at least partially covers the carrier and/or the first subset of the plurality of semiconductor dies, and
wherein the second external connection is connected to a second subset of the plurality of semiconductor dies, the second external connection protruding from the housing.

12. The method of claim 11, wherein mounting the insert onto the frame comprises:
aligning the insert with the frame using a plurality of holes in the insert; and
after the aligning, fixing the insert to the frame.

13. The method of claim 12, wherein fixing the insert to the frame comprises:
inserting a plurality of heat stake domes into the holes; and
after the inserting of the heat stakes, melting a top of one or more of the heat stake domes.

14. The method of claim 11, further comprising:
mounting a lid onto the frame,
wherein the second external connection protrudes from the lid.
